(19) United States
(12) Patent Application Publication
(10) Pub. No.: US 2025/0146971 A1
(43) Pub. Date: May 8, 2025

(54) GRAPHENE SENSORS AND A METHOD OF MANUFACTURE

(71) Applicant: Paragraf Limited, Cambridgeshire (GB)

(72) Inventors: Liam McDonnell, Cambridgeshire (GB); Robert Wallis, Cambridgeshire (GB)

(73) Assignee: Paragraf Limited, Cambridgeshire (GB)

(21) Appl. No.: 18/730,072

(22) PCT Filed: Jan. 31, 2023
(86) PCT No.: PCT/EP2023/052276

§ 371 Date: Jul. 18, 2024

(30) Foreign Application Priority Data
Feb. 4, 2022 (GB) 2201466.6

(51) Int. Cl. G01N 27/414; H01L 21/02; H01L 21/04; H01L 21/3065; H01L 21/308; H01L 21/311

(52) U.S. Cl. CPC G01N 27/4145; H01L 21/02172; H01L 21/02527; H01L 21/0262; H01L 21/042; H01L 21/3065; H01L 21/308; H01L 21/31122; H01L 21/31144

(57) ABSTRACT

There is provided a graphene sensor, preferably a graphene biosensor, comprising: a graphene layer structure provided on a non-metallic surface of a substrate, the graphene layer structure having an exposed, functionalised sample surface for receiving a sample for testing; first and second electrical contacts provided in contact with the graphene layer structure, and arranged on opposite sides of the functionalised sample surface; wherein each electrical contact is separated from the functionalised sample surface by an adjacent metal oxide layer, and wherein each electrical contact and adjacent metal oxide layer are capped with a passivating layer, whereby a sample for testing applied to the sample surface cannot contact the electrical contacts; and wherein the functionalised sample surface is devoid of photoresist.

The present invention relates to graphene sensors, more particularly sensors wherein the graphene layer structure has an exposed sample surface for receiving a sample for testing. The present invention also relates to a method for the manufacture of a graphene sensor, more particularly a method which comprises etching a precursor and, optionally, functionalising the sample surface. The present invention further relates to a container for storage and shipping which contains a plurality of said precursors. The present invention pertains particularly to graphene biosensors wherein the graphene layer structure has an exposed, functionalised sample surface.

Biosensors are well known devices whose importance in modern society have grown rapidly over the last couple of decades. Biosensors are important devices as tools for medical diagnoses as well as in the monitoring of diseases, including cancers and infectious diseases such as Sars-COV-2 (COVID-19) and sepsis, and drug discovery, together with applications in safety, such as food and environmental monitoring.

Biosensors are often the subject of extensive review. Examples of which include the special issue published in Sensors “Biosensors—Recent Advances and Future Challenges” (MDPI) and even more recently, “A Review on Biosensors and Recent Development of Nanostructured Materials-Enabled Biosensors” (Sensors 2021, 21, 1109). A biosensor is a device which generates a signal in response to a biological or chemical interaction with an analyte to be measured. A typical biosensor comprises a bioreceptor, transducer, electronics and a display, so as to measure the analyte (i.e. the substance of interest which is to be detected). There are many different conventional configurations of such components. In some systems, they may be integrated within a single apparatus, or the biosensor might form part of a system which includes a separate reader that has the display and carries out the diagnosis. Alternatively, in other systems, a cloud-based service is for data analysis/diagnosis and a remote computer provides the diagnosis and display.

A bioreceptor is a molecule or other biological element or species that serves to recognise the analyte. Bioreceptors include, though are not limited to, enzymes, cells, aptamers, DNA, RNA and antibodies. The interaction between the analyte and bioreceptor is also known as biorecognition and the biorecognition event (such as a change of light, heat, pH, charge or mass) is a form of energy which is then converted to a measurable signal by the transducer. The electronics serve to process and prepare the transducer signal for display by the display to a user. For example, a processor or a signal processing unit can process a voltage signal generated by the transducer by signal conditioning, such as by amplification and conversion of signals from analogue into the digital form. The processed signals are then quantified by the display unit of the biosensor. Such processing can take place remotely. The user of the biosensor device may be different to the user who analyses the output.

Graphene has found particular applicability in the fabrication of biosensors as a transducer material. Graphene is advantageous in view of its large surface area, electrical conductivity, high charge transfer rate and, most importantly, sensitivity resulting from its unique band structure as a two-dimensional material. Similarly, other two-dimensional materials have also been investigated for use in biosensor devices. For the biorecognition event to be converted into a signal, the bioreceptor needs to be immobilised on the graphene surface for which there are many such functionalisation techniques used in the art.

The most prominent methods for functionalising graphene simply involve immobilisation via non-covalent van der Waals interactions and π-π stacking. For example, one of the most common methods based on the reliable π-π stacking utilises 1-pyrenebutyric acid N-hydroxysuccinimide ester (PBASE) such that graphene-based biosensors have been developed using such technology. Other known methods involve immobilisation via covalent bonding to carbon atoms of the graphene.

These methodologies allowed for the rapid development of a graphene-based biosensor (specifically a GFET biosensor) effective for the detection of COVID-19 whereby the SARS-COV-2 spike antibody served as the bioreceptor, conjugated to the graphene sheet via a PBASE linker moiety (“Rapid Detection of COVID-19 Causative Virus (SARS-COV-2) in Human Nasopharyngeal Swab Specimens Using Field-Effect Transistor-Based Biosensor” (ACS Nano 2020, 14, 5135)).

Despite the efforts in the art to develop more sensitive biosensors, there are many challenges which remain. In particular, there still remains a need for a method which allows for the large-scale production of graphene-based biosensors which exhibit the desired sensitivity and reliability for effective use as a biosensor device. Accordingly, prior to functionalisation, there is a need for improved methods of manufacturing the biosensor architecture incorporating graphene which facilitate the subsequent functionalisation process thereby yielding superior devices.

After considerable research and development over recent years, graphene-based electronics and devices, notably graphene sensors, have begun making their way to the commercial market. Graphene field effect transistors (GFETs) suitable for sensing applications have been made commercially available by Graphenea™ together with their technical datasheets. One example of its use is provided in “Detection of an IL-6 Biomarker Using a GFET Platform Developed with a Facile Organic Solvent-Free Aptamer Immobilization Approach” (Sensors 2021, 21, 1335). It is known to manufacture graphene devices using conventional photolithography techniques. One such problem for large-scale device production is the patterning of the graphene. It is known that metals such as aluminium or titanium can be used as sacrificial layers and masks to define the graphene patterning during, for example, plasma etching (such as taught is “Enhanced photolithography with Al film insertion for large-scale patterning of CVD graphene” (Opt. Mater. Express 2018, 8, 2403) and US 2017/365562 A1). Furthermore, “Clean-Room Lithographical Processes for the Fabrication of Graphene Biosensors” (Materials 2020, 13, 5728) discloses methods which attempt to address these problems whereby sacrificial metallic masks are used to protect the wafer (the chip surface) from residues, except the areas around the channel, source, and drain, onto which the graphene film is transferred and later patterned. Also disclosed is the dielectric passivation of the metallic contacts on the chip surface.

Together with biosensors, other graphene-based sensors include chemical and gas sensors, all of which are well understood as operating on the same underlying principles and mechanisms. That is, the graphene layer structure acts as a transducer and generates a signal which may be detected and measured upon interaction with an analyte of interest. Generally, the graphene surface is functionalised with appropriate functionalisation suitable for interacting and detecting the analyte of interest. The analyte of interest may be a gas and provided in a gaseous sample or another chemical of interest and may be provided as a solution. Typically, such analytes are toxic or undesirable impurities which require monitoring for environmental and health reasons. Examples of such analytes include hydrogen peroxide, volatile organic compounds, toxic gases such as ammonia, nitrogen oxides and sulfur oxides, as well as heavy metals such as cadmium, lead and mercury. Naturally, sensors designed with bioreceptors provide biosensors for the detection of biomolecules as the analytes of interest. “Graphene based chemical sensors” (Sci. Lett. 2105, 4, 162) provides an overview of such sensor applications and “Recent Developments in Graphene-Based Toxic Gas Sensors: A Theoretical Overview” (Sensors 2021, 21, 1992) provides an overview of graphene functionalisations for toxic gas sensors.

US 2017/102358 A1 relates to field effect transistors and methods of making and using the same for sequencing, diagnostics, and bioinformatics processing. In the transistors disclosed, the source and drain electrodes are buried in the substrate or are otherwise provided beneath the two-dimensional material.

US 2021/396708 A1 relates to a sensing device for detecting harmful analytes, and more particularly to a sensing device including a biofunctionalized three-dimensional (3D) graphene layer.

However, there remains a problem for graphene-based sensors, especially biosensors, in that reliable techniques are required to manufacture such devices with improved sensitivity, in particular for large-scale and mass manufacture of the devices with improved uniformity between the devices manufactured. The inventors developed the present invention with the aim of overcoming these problems in the prior art.

Thus, in a first aspect of the present invention, there is provided a graphene sensor, preferably a graphene biosensor, comprising:
a graphene layer structure provided on a non-metallic surface of a substrate, the graphene layer structure having an exposed, functionalised sample surface for receiving a sample for testing;
first and second electrical contacts provided in contact with the graphene layer structure, and arranged on opposite sides of the functionalised sample surface;
wherein each electrical contact is separated from the functionalised sample surface by an adjacent metal oxide layer, and wherein each electrical contact and adjacent metal oxide layer are capped with a passivating layer, whereby a sample for testing applied to the sample surface cannot contact the electrical contacts; and
wherein the functionalised sample surface is devoid of photoresist.

In a second aspect of the invention, there is provided a graphene sensor comprising:
a graphene layer structure provided on a non-metallic surface of a substrate, the graphene layer structure having an exposed sample surface for receiving a sample for testing;
first and second electrical contacts provided in contact with the graphene layer structure, and arranged on opposite sides of the sample surface;
wherein each electrical contact is separated from the sample surface by an adjacent metal oxide layer, and wherein each electrical contact and adjacent metal oxide layer are capped with a passivating layer; and
wherein the sample surface is devoid of photoresist.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present invention relates to graphene sensors wherein the sample surface provided by a graphene layer structure is devoid of photoresist. The inventors have arrived at such products in their development of a method of manufacture which completely avoids application of photoresist to the surface of the graphene such that there is no possibility of contamination of the graphene surface with photoresist or photoresist residues.

For large-area production of graphene, it is ubiquitous in the art to manufacture graphene by CVD on catalytic metal substrates. It is then necessary to transfer the graphene to the desired substrate and this is achieved by standard transfer processes. Invariably, this requires the application of an organic polymer and chemical etching of the catalytic metal substrate. Typically, the metal substrate is a copper foil and the organic polymer is polymethylmethacrylate (PMMA). PMMA is also an industry standard photoresist (also simply known as a resist) and is used in graphene patterning by standard photolithographic techniques whereby the resist is patterned directly on the graphene surface and exposed portions of underlying graphene are etched away. The present invention avoids any contact of photoresist during both photolithography and during graphene production.

In order to achieve desired sensitivity and device performance, sensors require clean surfaces. Whilst methods have been developed to clean the graphene transfer polymer from the graphene surface (such by solvent washing, annealing or sacrificial metal deposition and removal), it is not possible to remove all traces and all residues of these materials. Furthermore, it is essential for the large-scale mass manufacture of sensors, in particular biosensors, that each device has the same electronic properties such that commercial products may reliably be used for detection and diagnosis since the degree of contamination from residues is difficult to control and therefore, so are the resulting electronic properties and responses to analytes. The sensors of the present invention are devoid of photoresist (and equally graphene transfer polymers, and residues thereof). This is achieved by the method of the present invention which avoids contacting the graphene with photoresist and graphene transfer polymer.

As described herein, the method of manufacture of a sensor comprises etching a metal oxide layer of a precursor (also described in greater detail herein) to expose the graphene surface. In first instance, this results in the formation of graphene sensor in accordance with the second aspect, whereby the sensor comprises an exposed sample surface provided by the graphene layer structure, that is not functionalised, but is devoid of photoresist and like. Such a graphene sensor is suitable for receiving and then sensing and detecting gaseous analytes from gaseous samples. The graphene sensor of the second aspect may therefore be referred to as a graphene gas sensor. The gas sensor is an intermediate in the manufacture of a sensor according to the first aspect of the invention, which is a preferred graphene sensor. In the sensor according to the first aspect of the invention, the sample surface is functionalised to provide an exposed, functionalised sample surface which is suitable for receiving a sample for testing (which may be a gaseous or liquid sample, solution or suspension as is known in the art).

In a most preferred embodiment, the graphene sensor is a graphene biosensor. Accordingly, the discussion herein with respect to a biosensor applies equally to other sensors of the first and second aspects, unless the context clearly dictates otherwise (such as in respect of functionalisations). As described in the background, the functionalisation of a sensor is not particularly limited and the present invention may utilise functionalisations known to those skilled the art for binding the target analyte and the subsequent sensing and detection of said analyte. As will be appreciated, the graphene biosensor provides the bioreceptor (from the functionalisation of the sample surface) and transducer (in the form of the graphene layer structure) as described in the background though other functionalisations (i.e. a more general analyte-receptor) which target binding of other analytes, such as toxic gases, heavy metals and organic compounds, will provide corresponding graphene chemical sensors. The graphene sensor device may be integrated within a sensor (i.e. a sensor apparatus) which comprises the necessary electronics and display for processing and displaying an output which allows determination of whether or not a sample composition comprises a predetermined analyte. Alternatively, the graphene sensor may be used in connection with the necessary electronics and display (i.e. wired or wirelessly; directly or remotely) as part of a system.

As discussed herein, the method may manufacture the graphene sensor of the first and second aspects. Equally, the sensors may be obtained by the method described herein. By extension, any feature described in respect of the graphene sensors may be applied to the method and vice versa.

### Graphene Sensors

The graphene sensor comprises a graphene layer structure provided on a non-metallic surface of a substrate, the graphene layer structure having an exposed, optionally functionalised, sample surface for receiving a sample for testing (i.e. whereby the sample surface is provided by the uppermost monolayer of graphene).

Graphene is a very well-known two-dimensional material referring to an allotrope of carbon comprising a single layer of carbon atoms in a hexagonal lattice. Graphene, as used herein, refers to a graphene layer structure which consists of one or more monolayers of graphene. Accordingly, the sensor encompasses those having a monolayer of graphene as well as multilayer graphene. Preferably, graphene refers to a graphene layer structure having from 1 to 10 monolayers of graphene. A monolayer of graphene is particularly preferred in view of the unique electronic properties associated with the “Dirac cone” band structure of a single graphene sheet. Nevertheless, multilayer graphene may also be preferred, such as 2 or 3 layers of graphene which permits modulation of the band gap.

Whilst the present invention is described with respect to a graphene layer structure, it will be appreciated that equivalent two-dimensional materials may also be used in its place so as to achieve substantially the same effect. As described for graphene, monolayer silicene (a silicon equivalent to graphene), monolayer phosphorene (an all-phosphorus equivalent to graphene) and monolayer TMDCs such as MoS₂ are preferred two-dimensional materials for a sensor.

The graphene layer structure may be undoped or may be doped with up to 10 at % doping elements. In some preferred embodiments, the doped graphene layer structure is doped with a total of from 1 at % to 10 at % doping elements selected from nitrogen (N), phosphorus (P), magnesium (Mg), zinc (Zn), boron (B), oxygen (O) and bromine (Br), preferably nitrogen. Preferably, the graphene is doped with at least 2 at %, preferably at least 3 at % doping elements. On the other hand, the inventors have found that there is an upper limit as to the effective amount of doping before the properties of the functionalised two-dimensional material are unduly negatively affected by the disruption to the sp² hybridised structure. In particular, 10 at % provides an upper limit, which is preferably at most 7.5 at %, more preferably at most 5 at %. Dopant concentrations may be determined using conventional techniques in the art such as X-ray photoelectron spectroscopy (XPS).

It is preferred that the graphene layer structure is not obtained by reduction of graphene oxide which inevitably is contaminated with various oxygen-based impurities (hydroxyl and epoxy groups). Furthermore, such techniques also result in highly defective graphene layers resulting from the physical manipulation required to obtain graphene via such route. This does not give rise to the preferred substantially flat sample-surface obtainable by the method disclosed herein. It follows that it is preferred that the graphene layer structure comprises less than 1 at % oxygen (O), preferably less than 0.5 at % oxygen, more preferably less than 0.1 at % oxygen. Similarly, it is preferred that the graphene does not comprise any other dopants, i.e. less than 1 at % total of any other elements (in particular elements except those discussed herein).

The graphene layer structure is provided on a non-metallic surface of a substrate. In accordance with the method disclosed herein, the graphene may be formed directly on the non-metallic surface of the substrate by CVD. Such a method does not require any transfer steps and therefore avoids contacting the graphene layer structure with any photoresist or transfer polymer such that the sensor is devoid of these materials (which may be referred to generally as being devoid of organic polymer). Moreover, such a method avoids the inevitable copper contamination from growth on copper foil substrates. Whilst described in greater detail with respect to the method of manufacture, a graphene layer structure may be used to refer to the as-deposited graphene which may then be patterned into any desired shape and configuration for a sensor.

It is preferred that the substrate comprises silicon (Si), silicon carbide (SiC), silicon nitride (Si₃N₄), silicon dioxide (SiO₂), sapphire (Al₂O₃), aluminium gallium oxide (AGO) hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (SC₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor such as aluminium nitride (AIN) and gallium nitride (GaN). Preferably at least the growth surface on which the graphene is formed comprise these materials and preferably the entire substrate comprises these materials. Such substrates are particularly suitable for high-quality graphene growth directly thereon, especially by the method referred herein (including that disclosed in WO 2017/029470). Sapphire is most preferred.

The sensor comprises first and second electrical contacts provided in contact with the graphene layer structure, and arranged on opposite sides of the sample surface. Typically, electrical contacts are metallic contacts made of metal, such as chromium, titanium, aluminium, nickel and/or gold, preferably titanium and/or gold.

The sensor has first and second electrical contacts provided in contact with said graphene layer structure (i.e. so as to provide an electrical connection with the graphene layer structure). The relative arrangement of such contacts at opposite sides of the sample surface is well-known in the art and serves to define a sample-surface of the transducer, which in the present invention is the graphene layer structure, for receiving an analyte composition therebetween the contacts. That is, an analyte composition is that which is to be tested and provides the analyte dispersed therein (typically a solution). For example, an analyte composition may be blood, saliva, urine, or a diluted solution thereof, especially for a biosensor. In the present invention, the contacts are provided on the same surface of the graphene as that which provides the sample surface. As will be appreciated, a sensor is for testing and detecting the presence of such an analyte and a lack of response will provide the user with a negative result indicating the lack of analyte in the sample composition being tested. Where the sample surface is functionalised, any appropriate functionalisation which provides an analyte-receptor immobilised on the graphene layer structure may be used. In other words, a functionalised graphene layer structure may be considered as a graphene layer structure comprising an analyte-receptor immobilised on the exposed surface thereof.

Typically, a functionalised sample surface comprises an organic linker moiety which comprises two functional groups, a first of which serves to immobilise the analyte-receptor to the surface. For example, this may comprise non-covalent immobilisation through a pyrene functional group or covalent immobilisation through diazonium binding or alkylation of dopant atoms. The second functional group may comprise a thiol, amine or carboxylic acid functional group which is used to attach receptors, for example, biomolecules such as antibodies and aptamers. Functionalised surfaces may include inorganic compounds such as gold nanoparticles.

In some preferred embodiments, the first and second electrical contacts are provided so as to contact an edge of the graphene layer structure, thereby separating the first and second contacts by the graphene layer structure surface therebetween. In such instance the first and second electrical contacts are provided in contact with an edge of the graphene layer structure and extend onto an adjacent portion of a surface thereof. More particularly, contacts extend onto an “upper” surface, that is the same surface of the two-dimensional material which comprises said functionalisation. In other words, the first and second electrical contact are provided on the graphene layer structure.

Each electrical contact is separated from the functionalised sample surface by an adjacent metal oxide layer. That is, each electrical contact is coated with a metal oxide (and may therefore be referred to as a layer) whereby the metal oxide also contacts the graphene layer structure directly adjacent the electrical contact (and around the entire perimeter of the electrical contact where in contact with the graphene). The metal oxide layer is provided on the same surface as the electrical contact and therefore isolates the electrical contact from the functionalised surface. Such a metal oxide layer is particularly beneficial for a sensor for testing a liquid sample as the metal oxide layer prevents the liquid sample from contacting the electrical contact (and shorting or otherwise allowing undesired current flow).

Preferably, the metal oxide layer is Al₂O₃, ZnO, TiO₂, ZrO₂, HfO₂, MgAl₂O₄ or YSZ, preferably aluminium oxide (Al₂O₃) or hafnium oxide (HfO₂), more preferably aluminium oxide. Preferably, the thickness of the metal oxide layer is at least 2 nm, for example from 5 nm to 5 μm, preferably from 10 nm to 1 μm (i.e. as measured perpendicular to the plane of the substrate). In some preferred embodiments, the thickness is from 2 to 50 nm, preferably from 5 to 30 nm. Preferably, the width of the metal oxide layer is at least 0.5 μm and/or at most 5 μm, such as from 1 μm to 3 μm. The width is the thickness of the metal oxide layer as measured from the contact to the exposed sample surface (i.e. parallel to the plane of the substrate). Such a width is a result of photolithographic processing as described with regard to the method herein in view of the resolution limitations and the need to ensure the contacts are coated by metal oxide.

Each electrical contact and adjacent metal oxide layer are capped with a passivating layer, whereby a sample for testing applied to the sample surface cannot contact the electrical contacts. As will be appreciated, the electrical contacts may extend along the surface of the substrate and be exposed at a distal location for connection to an electrical circuit. Typically, a liquid sample may be a few drops in the hundreds or tens of microlitres (such as less than 100 μL) such that when the sample is applied to the sample surface, the sample cannot directly contact the electrical contacts.

The passivating layer serves to coat the electrical contacts so as to prevent the sample from contacting the electrical contacts. The passivating layer extends on and across at least the metal oxide which is directly adjacent and in contact with the electrical contacts. In some embodiments, the metal oxide may be patterned to provide a perimeter or a boundary of the graphene layer structure and the passivating layer may extend across the entire metal oxide, and preferably across the adjacent substrate thereby covering the edges of the underlying graphene layer structure.

Passivating layers are understood as those which provide an air-and moisture-barrier so as to passivate the underlying layers from contamination. The passivating layer preferably comprises aluminium oxide, silicon oxide, silicon nitride, photoresist and/or synthetic resin. Synthetic resins are well-known and some may also be known photoresists, such as PMMA and SU-8. Synthetic resins include epoxy resins and acrylate resins. Preferably, the passivating layer is etch-resistant. The etch-resistant passivation layer may comprise a sub-layer which is not etch-resistant (e.g. photoresist on aluminium oxide). Similar to the thickness of the metal oxide, preferably the thickness of the passivation layer is at least 5 nm.

As already described, the sample surface is devoid of photoresist. This allows for improved functionalisation due to the absence of contaminants. This is particularly true for biosensor functionalisation which requires organic linkers immobilised to the graphene surface. By way of example only, PBASE linker moieties rely on π-π stacking of the pyrene unit and the graphene surface, and this in particular is interrupted by residues on the surface of the graphene. In turn, these improvements allow for higher sensitivity and device performance.

The graphene biosensor is particularly effective and therefore preferred for use in the detection of infectious diseases (because both speed and sensitivity of a device is critical) which includes viral diseases such as SARS-COV-2, Influenza, HIV/AIDS, MERS, Ebola, Zika, Dengue, Malaria, and bacterial diseases such as Sepsis, Tuberculosis, Pneumonia, Gonorrhoea, Cholera. The graphene biosensor is therefore also effective for detection of cardiovascular diseases (where speed is important) and oncology (where accuracy is more important than speed).

In particularly preferred embodiments, the graphene sensor comprises a third electrical contact. As is known in the art, the first and second electrical contacts in direct contact with the graphene layer structure may also be referred to as source and drain contacts. The third electrical contact provides a gate electrical contact. Suitable configurations of gate contacts are known. For example, a “back gate” may be provided whereby the third electrical contact is provided under the graphene layer structure separated therefrom by the substrate, or a layer thereof in cases wherein the third contact is provided embedded within the substrate. The third electrical contact may preferably be a conductive layer of the substrate embedded within non-conductive layers of the substrate and arranged vertically beneath the sample surface of the graphene layer structure.

In a preferred embodiment, a third electrical contact is provided on the substrate (and therefore separated from the graphene layer structure and other layers described). The third contact is exposed, at least a portion thereof, which is configured (arranged on the substrate) in order to contact the liquid sample when applied to the graphene sensor. In other words, the exposed third contact will be provided proximal to the sample surface so that the sample composition contacts both the sample surface and the third contact.

The sensor device has so far been described with reference to a single graphene layer structure having at least first and second electrical contacts and a sample-surface between said electrical contacts for receiving a sample (an analyte composition) to be tested. This may be referred to as a sensor cell. In a preferred embodiment, the sensor comprises one or more further graphene layer structures, each having a sample-surface between their electrical contacts for receiving the sample to be tested. In other words, it is preferred that the sensor comprises two or more sensor cells.

Such an arrangement may be referred to a multiplex of sensors (multiplexing) and are preferred for biosensors. In use, the sample surface of each biosensor cell of the biosensor is contacted with the common analyte composition to be tested. The sample surface of the graphene layer structure of each biosensor cell may be functionalised with the same analyte-receptor. This is advantageous for improving the reliability of the signal output due to the presence of multiple sensors. In other embodiments, the sample surface of one or more biosensor cells may be functionalised with a different analyte-receptor to the first allowing for the simultaneous detection of two (or more) analytes of interest in a single sample. Microfluidics and/or physical structures may be used to distribute the sample across the sample surfaces.

### Container Containing a Plurality of Precursors

The present invention also relates to a container that is suitable for storage and shipping, which contains a plurality of precursors. Each precursor is for the manufacture of a graphene sensor, such as by the method described herein. More particularly, each precursor is preferably manufactured by the method.

A container is a sealed package, sealed to prevent ingress or egress of the atmosphere extending the lifetime of the precursors contained therein. Accordingly, such precursors may be stored (for example for more than 3 months and even more than 6 months) and unpackaged as and when required by the user to prepare a graphene sensor, such as by the present method. Preferably, the precursors are contained in an atmosphere consisting essentially of an inert gas, such nitrogen or argon.

A plurality of precursors may be provided on a common substrate, such as an array. Alternatively, each precursor may be a separate product, for example, the precursors may have been manufactured on a common substrate and subsequently diced into individual precursors before packaging into a container. Preferably, each precursor is intended to refer to a precursor which is intended to provide a sensor device. Such a device as described herein may comprise one or more sensor cells which may share a common gate contact.

Each precursor comprises a graphene layer structure provided on a non-metallic surface of a substrate, wherein the graphene layer structure is formed on the non-metallic surface of the substrate by CVD. As a result, the graphene layer structure is devoid of photoresist.

Each precursor also comprises first and second electrical contacts in contact with the graphene layer structure, and arranged on opposite sides of the precursor; a metal oxide layer on and across the graphene layer structure, in contact with and between the first and second electrical contacts; and a passivating layer provided on the metal oxide layer and on and across the first and second electrical contacts; as described for the graphene sensors above.

The passivating layer defines an uncoated window of exposed metal oxide layer, the window arranged between the first and second electrical contacts. The uncoated window serves to define an underlying region of graphene layer structure which will be exposed to provide an exposed sample surface, and preferably functionalised thereafter with an analyte-receptor. By a window, it is meant that a portion of the underlying metal oxide layer is exposed, the passivating layer coating a portion of the metal oxide, specifically, the portion directly adjacent the electrical contacts. The metal oxide layer provides an additional barrier to contamination of the graphene layer structure enabling the precursor to be stored for an extended time period before use.

### Method of Manufacture of a Graphene Sensor

A further aspect of the present invention provides a method for the manufacture of a graphene sensor, the method comprising:
(i) providing a precursor as described herein;
(ii) etching the uncoated window of exposed metal oxide layer to form a graphene sensor having an exposed sample surface of the graphene layer structure for receiving a sample for testing; and optionally
(iii) functionalising the exposed sample surface to form a graphene sensor having a functionalised sample surface for receiving a sample for testing.

The method comprises etching the uncoated window of the precursor. The precursor is preferably provided by the method described hereinbelow. The window of uncoated metal oxide is etched thereby exposing the sample surface provided by the graphene layer structure. In accordance with the second aspect, the resulting product may be used as a gas sensor. Preferably, the sample surface is functionalised to provide an exposed, functionalised sample surface thereby forming a graphene sensor in accordance with the first aspect. Where the sample surface is functionalised with an analyte-receptor that is a biomolecule-receptor (a bioreceptor), the sensor is a biosensor.

In some embodiments, the metal oxide is etched using an alkaline solution (i.e. a pH of more than 7), preferably an aqueous alkaline solution. For example, the metal oxide may be etched using an aqueous sodium and/or potassium hydroxide solution. Preferably, the solution is relatively dilute, for example the pH of the etching solution is preferably from 8 to 13, more preferably from 9 to 12. In more preferred embodiments, the metal oxide is etched using an acidic solution (i.e. a pH of less than 7), preferably an aqueous acidic solution. For example, the metal oxide is preferably etched using a phosphoric acid solution, hydrofluoric acid solution or a buffered hydrofluoric acid solution. In a particularly preferred embodiment, the metal oxide is etched using a phosphoric acid solution comprising nitric acid (e.g. up to about 10 vol. % nitric acid, preferably up to about 5 vol. %, for example from 1 to 3 vol. %). Phosphoric acid is generally available for use in a concentration of at least 75 wt % in water (for example about 86 wt %). Hydrofluoric acid is generally available for use in a concentration of about 50 wt % in water. Nitric acid is generally available for use in a concentration of at least 68 wt % in water (for example about 68 wt %). The acidic solution may have a pH of from 0 to 6, preferably from 1 to 5, for example from 1 to 2.

During etching, the entire substrate is typically submerged in an etching bath of the etching solution for a time sufficient to etch the metal oxide and expose the graphene layer structure. Generally, the etching step takes at least 2 minutes, though this will depend on the thickness of the metal oxide layer. Preferably, the etching step is carried out for less than 60 minutes. The inventors have found that such etching does not damage the underlying graphene through monitoring by standard Raman and AFM techniques. On the other hand, it is known that some photoresist stripper solutions can damage the graphene which can even result in delamination from the substrate surface.

The inventors have found that photoresist materials are relatively complex, long chain organic compounds, which bind to the graphene surface due to π-π stacking and van der Waals forces, and saturate the graphene surface preventing proper functionalisation and moreover impacting the sensing function within the Debye length. Without wishing to be bound by theory, the inventors have found that the inorganic metal oxide has much lower adherence to the graphene surface and, where metal oxide residue may remain, these more inert traces are significantly less interfering with analyte detection than photoresist residues, leading to an improved device performance.

### Method of Manufacture of the Precursor

The method of manufacturing the graphene sensor will now be described further with reference to manufacturing the precursor. The steps described herein are preferably carried out in order.

Preferably, the precursor is obtained in a first method comprising:
(i) providing a substrate having a non-metallic surface;
(ii) forming a graphene layer structure on the non-metallic surface by CVD;
(iii) forming a metal oxide layer on and across the graphene layer structure;
(iv) applying a first photoresist to the metal oxide layer and patterning it to provide a first masked region;
(v) etching the metal oxide layer to retain only the metal oxide layer beneath the first masked region, exposing a portion of the graphene layer structure;
(vi) plasma etching the exposed portion of the graphene layer structure to retain only the graphene layer structure beneath the first masked region;
(vii) removing the first photoresist;
(viii) applying a second photoresist to the metal oxide layer and patterning it to provide a second masked region;
(ix) etching the metal oxide layer to retain only the metal oxide layer beneath the second masked region, exposing a portion of the graphene layer structure;
(x) depositing metal to form first and second electrical contacts, each in contact with the exposed graphene layer structure and an edge of the metal oxide layer; and
(xi) removing the second photoresist.

As will be appreciated, the general steps of applying a photoresist, patterning the resist so as to pattern the underlying layers, and subsequently removing the resist are well-known photolithography steps. The inventors sought to develop a method which allowed for the avoidance of photoresist directly on the graphene layer structure and, in combination with forming the graphene directly on the substrate by CVD, the use of a metal oxide layer ensures there is no photoresist or the like on the graphene in the resulting products (precursors and sensors). Furthermore, the inventors found that the method was particularly advantageous since the inclusion of a metal oxide layer in an intermediate precursor, a portion of the metal oxide layer could be retained in the sensor and simultaneously serve to protect the edges of the electrical contacts from being able to contact the sample composition.

The graphene layer structure is formed by CVD directly on the non-metallic surface of the substrate. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. One of the most common precursors for graphene growth is methane though other hydrocarbons may be used. Preferred compounds include those disclosed in UK Patent Application No. 2103041.6 (the contents of which is incorporated herein in its entirety) where it is preferred that the precursor is an organic compound comprising at least two methyl groups (—CH₃). The inventors have found that when forming graphene directly on non-metallic substrates, precursors beyond the traditional hydrocarbons methane and acetylene allow for the formation of even higher quality graphene, and by extension, doped graphene for use in the present invention. Preferably, the precursor is a C₄-C₁₀ organic compound, more preferably the organic compound is branched such that the organic compound has at least three methyl groups. Doped graphene is formed from a carbon-containing precursor which also contains the doping element. Alternatively, a further precursor containing the doping element may be introduced simultaneously with the carbon-containing precursor (and may be carbon-containing itself).

Preferably, the method involves forming graphene by thermal CVD such that decomposition is a result of heating the carbon-containing precursor. Preferably, the CVD reaction chamber used in the method disclosed herein is a cold-walled reaction chamber wherein a heater coupled to the substrate is the only source of heat to the chamber. Preferably, the temperature of the growth surface during CVD is from 700° C. to 1350° C., preferably from 800° C. to 1250° C., more preferably from 1000° C. to 1250° C. The inventors have found that such temperatures are particularly effective for providing graphene growth directly on the materials described herein by CVD.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the non-metallic surface). Accordingly, such an embodiment involves a “vertical” arrangement whereby the plane containing the precursor entry points is substantially parallel to the plane of the substrate surface (i.e. the growth surface).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470 (which is incorporated herein by reference), very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor. Such a method is particularly preferred for enabling the large-scale industrial manufacture of an array of precursors, and ultimately sensors, upon a single common substrate. This is particularly advantageous as this allows for consistent device fabrication with stable properties from one device to the next on a commercial scale. Individual precursors or sensors may be divided therefrom at the relevant stage using conventional means such as dicing.

Consequently, in a particularly preferred embodiment wherein the method of the present invention involves using a method as disclosed in WO 2017/029470, the method comprises:
providing a substrate on a heated susceptor in a CVD reaction chamber, the CVD reaction chamber having a plurality of cooled inlets arranged so that, in use, the inlets are distributed across the non-metallic surface of the substrate and have constant separation from the non-metallic surface of the substrate;
cooling the inlets to less than 100° C. (i.e. so as to cool the precursor);
introducing a carbon-containing precursor in a gas phase and/or suspended in a gas through the inlets and into the CVD reaction chamber; and
heating the susceptor to a temperature of at least 50° C. in excess of a decomposition temperature of the precursor, to provide a thermal gradient between the surface of the substrate and inlets that is sufficiently steep to thereby decompose the precursor and allow the formation of a graphene layer structure from the carbon released from the decomposed precursor;
wherein the constant separation is less than 100 mm, preferably less than 25 mm, even more preferably less than 10 mm.

For the same reasons, the method is preferred for enabling the manufacture of multiple biosensor cells for a single biosensor device (or an array of biosensor devices which comprise multiple biosensor cells). This is particularly advantageous as this allows for consistent device fabrication with stable properties from one device to the next on a commercial scale.

The preferred method further comprises forming a metal oxide layer on and across the graphene layer structure. The method by which the metal oxide layer is formed is not particularly limited. Suitable methods include those based on physical vapour deposition (PVD), such as by thermal evaporation or e-beam, or those based on chemical vapour deposition, such as atomic layer deposition (ALD). In some preferred embodiments, the metal oxide layer is formed by deposition of a metal layer and oxidation of the metal layer. This may be achieved by exposure to air, optionally with heating. ALD is a preferred method for forming a metal oxide layer. ALD is technique known in the art and comprises the reaction of at least two precursors in a sequential, self-limiting manner. Repeated cycles to the separate precursors allow the growth of a layer in a conformal manner (i.e. uniform thickness across the entire substrate, the surface of the graphene layer structure in the present method) due to the layer-by-layer growth mechanism.

The step of a applying a first photoresist to the metal oxide layer comprises patterning it to provide a first masked region. For example, patterning is typically carried out by exposing portions of the photoresist to UV light with the desired pattern. Depending on whether a negative or positive photoresist is used, the portion exposed or not exposed to the UV light is then washed away using a suitable solvent leaving behind the patterned photoresist thereby providing a mask (i.e. a first masked region) which protects the layers beneath. The first masked region may be shaped so as to provide the desired shape of the graphene layer structure of the final product.

Preferably, the method comprises manufacturing a plurality or an array of precursors across the substrate. Accordingly, the first photoresist and patterning thereof serves to shape the single graphene layer structure formed across the substrate into a plurality or an array of patterned graphene layer structures. As will be appreciated, the first masked region may therefore be a plurality of separate regions distributed across the metal oxide layer.

The method comprises etching the metal oxide layer to retain only the metal oxide layer beneath the first masked region, exposing a portion of the graphene layer structure. That is, the metal oxide layer is etched in all regions except in the first masked region. As described for the production of an array, a first region comprising a plurality of separate regions may therefore provide a single continuous region of exposed metal oxide layer. Alternative configurations though may be provided by appropriate patterning. By etching the metal oxide layer, the underlying graphene layer structure is exposed.

The method comprises plasma etching the exposed portion of the graphene layer structure to retain only the graphene layer structure beneath the first masked region. Plasma etching is a preferred method, preferably oxygen plasma etching since this provides clean and effective removal of the carbon from the substrate surface. Other etching techniques may be used. As for the metal oxide layer, the graphene layer structure is therefore patterned to have the same shape as the metal oxide layer and first photoresist thereon. The first photoresist is then removed using conventional methods.

The method then comprises applying a second photoresist to the metal oxide layer and patterning it to provide a second masked region on the same basis as the first photoresist. The purpose of the second photoresist is to pattern on a portion of the metal oxide layer, specifically by exposing a portion adjacent the edge of the metal oxide layer. Where the edge is conterminal with the underlying graphene layer structure, removing a portion of the metal oxide layer permits an electrical contact to subsequently be deposited on the surface of the graphene layer structure adjacent the edge.

Thus, the method comprises etching the metal oxide layer to retain only the metal oxide layer beneath the second masked region, exposing a portion of the graphene layer structure on the same basis as the first step of etching the metal oxide layer.

Then metal is deposited to form first and second electrical contacts, each in contact with the exposed graphene layer structure and an edge of the metal oxide layer. Conventional techniques for metal deposition may be used to form the electrical contacts (e.g. e-beam deposition). The metal is deposited to contact the exposed surface of the graphene layer structure and extend to the edge of the metal oxide layer. Typically, the metal is deposited across the intermediate though a shadow mask may be used. For this reason, the second photoresist may also provide a mask in other regions of the substrate to prevent metal from depositing on the substrate surface. Equally, the second photoresist may be used to pattern a third electrical contact proximal to the graphene layer structure to provide a gate contact. That is, deposition of the metal in this step may form first, second and third electrical contacts. The second photoresist is then removed using conventional techniques. Such a step is also known as a “lift-off”. Metal deposited on the surface of the photoresist is also removed as a result of the removal of the resist to leave only the metal which was not deposited on the resist mask.

In an alternative method to the above steps, a precursor is obtained in a second method comprising:
(i) providing a substrate having a non-metallic surface;
(ii) forming a graphene layer structure on the non-metallic surface by CVD;
(iii) forming a patterned metal oxide layer on the graphene layer structure;
(vi) plasma etching the graphene layer structure to retain only the graphene layer structure beneath the patterned metal oxide layer;
(viii) applying a second photoresist to the metal oxide layer and patterning it to provide a second masked region;
(ix) etching the metal oxide layer to retain only the metal oxide layer beneath the second masked region, exposing a portion of the graphene layer structure;
(x) depositing metal to form first and second electrical contacts, each in contact with the exposed graphene layer structure and an edge of the metal oxide layer; and
(xi) removing the second photoresist.

Most of the steps of this second method are identical to those already described for the first method. However, such a method is one example of alternative methods which may be used to obtain a precursor. Specifically, step (iii) in the second method, of forming a patterned metal oxide layer on the graphene layer structure, replaces steps (iii)-(v) and (vii) of the first method. Therefore, whilst step (viii) of the second method refers to the step of applying a second photoresist, the photoresist is not limited by the term “second”, however, its application and patterning is as described in respect of step (viii) of the first method. Direct formation of a patterned metal oxide layer without requiring the subsequent photolithography steps may be achieved using PVD deposition techniques, preferably thermal evaporation of the metal oxide through a shadow mask.

Alternatively, it is also preferred that the precursor is obtained in a third method comprising:
(I) providing a substrate having a non-metallic surface;
(II) forming a graphene layer structure on the non-metallic surface by CVD;
(III) forming a metal oxide layer on and across the graphene layer structure;
(IV) applying a first photoresist to the metal oxide layer and patterning it to provide a first masked region;
(V) etching the metal oxide layer to retain only the metal oxide layer beneath the first masked region, exposing a portion of the graphene layer structure;
(VI) depositing metal to form first and second electrical contacts, each in contact with the exposed graphene layer structure and an edge of the metal oxide layer;
(VII) removing the first photoresist;
(VIII) applying a second photoresist to the metal oxide layer and the first and second electrical contacts, and patterning it to provide a second masked region covering the first and second electrical contacts and a portion of the metal oxide layer;
(IX) etching the metal oxide layer to retain only the metal oxide layer beneath the second masked region, exposing a portion of the graphene layer structure;
(X) plasma etching the exposed portion of the graphene layer structure to retain only the graphene layer structure beneath the second masked region; and
(XI) removing the second photoresist.

Steps (I)-(V) are equivalent to those already described for steps (i)-(v) of the first method. In this third method of manufacturing the precursor, metal is deposited before the step of plasma etching the graphene layer structure. Nevertheless, it remains essential that the metal is deposited in contact with the edge of the metal oxide such that the metal oxide may serve as a coating to protect the electrical contact from contacting the sample during use.

Accordingly, after having deposited the electrical contacts and removed the first resist, a second resist serves to pattern the graphene layer structure. by first protecting the deposited contacts and etching both a portion of the metal oxide layer and corresponding underlying graphene layer structure. Such a method provides contacts solely on the surface of the graphene and not the adjacent substrate. So as to provide the precursor, it will be appreciated that the retained metal oxide layer beneath the second masked region is a portion on and across the graphene layer structure, in contact with and between the first and second electrical contacts.

Any of these methods may then further comprise the steps of:
(xii-a) applying a third photoresist and patterning it to provide a third masked region on a portion of the metal oxide layer spaced apart from the first and second electrical contacts;
(xiii-a) forming a passivation layer on the first and second electrical contacts and adjacent unmasked metal oxide layer;
(xiv-a) removing the third photoresist.

That is, preferably, a third photoresist is applied and patterned to provide a third mask which is, spaced apart (i.e. laterally) from the first and second electrical contacts. In other words, the third mask is not over the electrical contacts and is not over an adjacent portion of the metal oxide layer. Preferably, the mask is spaced at least 0.5 μm from each contact such that the eventual width of the underlying metal oxide (i.e. after etching of the window as described herein) is at least 0.5 μm.

Step (xiii-a) preferably comprises forming a passivation layer across the intermediate, thereby covering the first and second electrical contacts and adjacent metal oxide layer. Preferably, the passivation layer is a metal oxide, or may preferably be aluminium oxide, silicon oxide and/or silicon nitride. The third photoresist is then removed and any passivation layer material deposited thereon is also removed as a result. The third masked region defines at least the window of the exposed metal oxide layer in the product. The third photoresist may also be patterned on the substrate to protect the streets between precursors from the passivation layer material.

In some embodiments, it is preferred to, in a step (xv-a), apply a fourth photoresist and pattern it to provide a mask on and across the passivation layer. The fourth photoresist serves to provide an etch-resistant passivation layer such that a window of exposed metal oxide layer is retained (i.e. preferably the fourth resist is not on the metal oxide layer). The resulting precursor is then preferably used in the method for the manufacture of a graphene sensor.

In an alternative, the passivation layer consists of photoresist and steps (xii-a)-(xv-a) are not required. Instead, the third photoresist is, in a step (xii-b), applied and patterned to provide a third masked region on the first and second electrical contacts and adjacent portions of the metal oxide layer thereby defining an exposed window of metal oxide layer. The third masked region therefore extends onto portions of the metal oxide layer adjacent to the electrical contact, essentially the negative of the previous alternative.

Such methods of preparing the precursor are advantageous because they are based on photolithography but avoid direct contact of the photoresist with the graphene layer structure. Photolithography permits the manufacture of small-scale devices (i.e. with resolution in the single microns, typically at least 0.5 micron) which are problematic to achieve with alternative methods. The small devices allow for greater density on a substrate during mass manufacture which is also essential for commercialisation. In addition, this allows each sensor device to comprise a higher number of smaller sensing regions (sensor cells). This increases the number of independent measurements and allows for improved sensing reliability and higher yield of fabricated devices.

### Methods of Testing for an Analyte

In a further aspect there is provided a method of testing for an analyte (i.e. a method of testing a sample composition for a predetermined analyte), the method comprising applying a sample to the exposed, functionalised sample surface of the graphene sensor of the first aspect (i.e. contacting the sample surface with a sample composition) and observing an electrical output to determine whether or not the sample contains the intended analyte. The sensor may be used for testing a gaseous sample, though it is preferred that the sample is a liquid sample. Preferably, the graphene sensor is a graphene biosensor. In determining whether or not the sample contains the intended analyte, the graphene sensor having increased sensitivity over known sensors allows for either a qualitative determination of the mere presence of the analyte or, preferably, a quantitative determination of the amount, or concentration, of the intended analyte in the sample composition.

In a further aspect method of testing for a gaseous analyte, the method comprising applying a gaseous sample to the exposed sample surface of the graphene sensor of the second aspect and observing an electrical output to determine whether or not the gaseous sample contains the intended analyte.

A preferred method comprises using a graphene biosensor as described herein which comprises an appropriate analyte-receptor for the biorecognition of a predetermined analyte. The sample composition may be any typical composition for testing. For example, a sample may derive from a human or animal, such as a blood, urine, saliva, sweat, tears, faeces, breath, plasma, or sperm sample. In other embodiments, the sample composition is a food sample, an environmental sample (e.g. river, sea or waste water, ground or soil samples) or may be of plant origin (e.g. tree or crop samples). Preparation of suitable samples is well known; water samples may be used directly, whereas other samples may be dissolved in an appropriate solvent (e.g. water) and filtered as necessary for testing.

The composition is contacted with the sample-surface of the graphene layer structure so that, upon interaction with the analyte, if present in the sample composition, an electrical current provided by the contacts and through the graphene will be modulated. Thus, by observing an electrical output between the contacts, a user may determine whether the predetermined analyte (as determined by the nature of the analyte-receptor of the biosensor device) is present in the sample composition. For example, a positive or negative result may be determined by the conductance of the graphene exceeding a predetermined threshold.

### FIGURES

The present invention will now be described further with reference to the following non-limiting Figures, in which:

FIG. 1 illustrates a method of patterning graphene and the metal oxide layer by photolithography.

FIG. 2 illustrates a method of forming electrical contacts by photolithography.

FIG. 3 illustrates a method of forming a passivation layer to define an uncoated window of exposed metal oxide by photolithography, and etching the window to form a sensor.

FIG. 4 illustrates another method of forming a passivation layer to define an uncoated window of exposed metal oxide by photolithography, and etching the window to form a sensor.

FIG. 5 is a plan view of a precursor manufactured by the methods illustrated in FIGS. 1 and 2 and in part by the method illustrated in FIG. 3.

FIG. 6 is a plan view of a graphene sensor manufactured by the methods illustrated in FIGS. 1 to 3.

FIG. 7 illustrates a method of functionalising the exposed sample surface of a graphene sensor.

FIG. 8 illustrates a method of testing for an analyte in a sample composition using a graphene biosensor.

FIG. 9 is a plan view of a graphene biosensor device in use, comprising a plurality of graphene biosensors on a common substrate which comprises a third electrical gate contact.

FIG. 10 illustrates a method of transferring graphene to a substrate and patterning by photolithography.

FIG. 11 illustrates a method of forming electrical contacts and a passivation layer over said contacts by photolithography.

FIG. 12 illustrates a method of transferring graphene to a pre-patterned substrate comprising electrical contacts.

FIG. 13 is a plot of the shift in Dirac point observed (in mV) of ten comparative COVID aptamer functionalised GFET biosensors upon sequential addition of 10 k, 100 k and 1,000 k copies of deactivated COVID virus.

FIG. 14 is an exemplary I-V trace of a comparative biosensor, specifically FET 13 of FIG. 13.

FIG. 15 is a plot of the shift in Dirac point observed (in mV) of nine COVID aptamer functionalised GFET biosensors in accordance with the present invention upon sequential addition of 10 k, 100 k and 1,000 k copies of deactivated COVID virus.

FIG. 16 is an exemplary I-V trace of a biosensor in accordance with the present invention, specifically FET 07 of FIG. 15.

FIG. 17 is a plot of the average changes and calculated standard deviations for the data shown in FIGS. 13 and 15.

FIG. 18 is an I-V plot measuring the current (A) against gate voltage (V) for an exemplary graphene FET manufactured without use of a protective metal oxide layer.

FIG. 19 is an I-V plot measuring the current (A) against gate voltage (V) for an exemplary graphene FET manufactured with use of a protective metal oxide layer in accordance with the present invention.

FIG. 20 is a box plot comparing the transconductance (mS/V) of a plurality of exemplary FETs manufactured either with or without use of a protective metal oxide layer.

FIG. 21 is a box plot comparing the Dirac Point (V) of the same exemplary FETs measured in FIG. 20.

FIG. 22 is a box plot comparing the channel resistance (kΩ) of the same exemplary FETs measured in FIGS. 20 and 21.

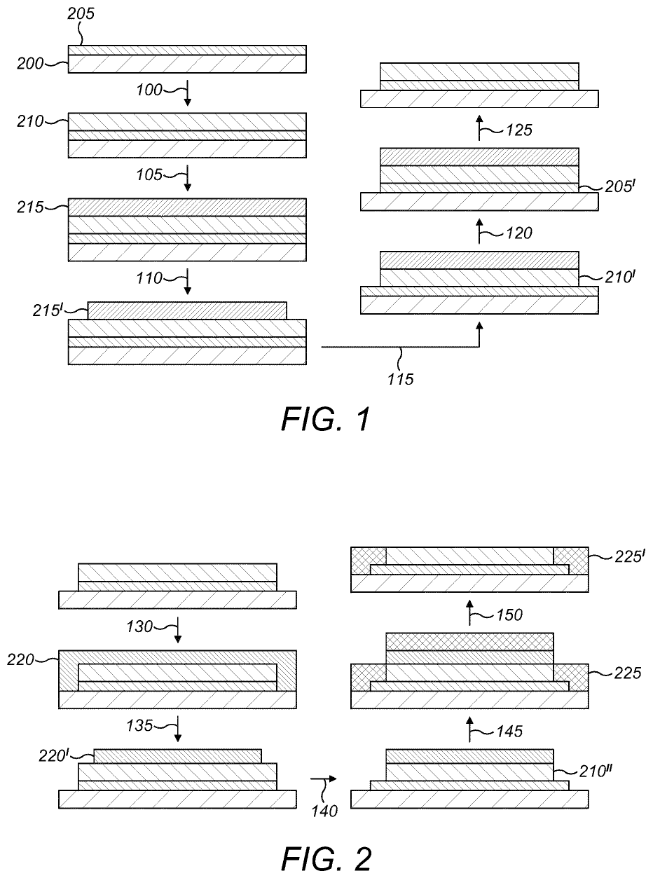

FIG. 1 illustrates a method of patterning graphene and the metal oxide layer by photolithography. A graphene monolayer 205 (referred to throughout the Figures as graphene 205) is formed directly on a surface of a sapphire substrate 200 by CVD (not shown). A metal oxide layer 210 is then formed 100 on the exposed surface of the graphene 205 by depositing a 1 nm thick seed of aluminium followed by 20 nm of aluminium oxide by ALD. A first photoresist 215 is applied 105 to the surface of the metal oxide layer 210. Conventional photolithography materials and techniques may be used. Typically, a solution containing the photoresist materials is spin coated across the surface. The photoresist materials may comprise polymerisable material (e.g. methyl methacrylate) and patterned/masked UV light is used to cure and polymerise one or more portions of the photoresist materials so as to pattern the photoresist 215 and remove 110 the portions not exposed to UV light to provide a first masked region defined by the patterned photoresist 215′.

The exposed portion of the metal oxide layer 210 is then etched 115 to retain only the metal oxide layer 210′ beneath the first masked region. As a result, corresponding portions of the underlying graphene 205 are exposed which are then plasma etched 120 to retain only the graphene 205′ beneath the first masked region. Finally, the first patterned photoresist 215′ is removed by washing with a solvent to provide a patterned stack of metal oxide 210′ on graphene 205′ on the substrate 200.

Such steps correlate with steps (i) to (vii) described herein in respect of the first method of manufacturing the precursor.

FIG. 2 illustrates a method of forming electrical contacts by photolithography. The method of FIG. 2 continues the method shown in FIG. 1. However, as described herein, alternative methods may be used to provide a patterned metal oxide and graphene stack.

A second photoresist 220 is applied 130 to the surface of the metal oxide layer 210′ and on adjacent portions of the substrate 200 which is then patterned 135 to provide a second masked region defined by the patterned second photoresist 220′ which exposes a portion adjacent the edge of the metal oxide layer (and on opposite sides suitable for providing source and drain contacts on the underlying graphene). The second patterned photoresist 220′ also covers and protects regions of the substrate not adjacent to the stack (not shown). As described herein, first, second, third photoresists (and so forth) may each be applied and patterned using photolithography techniques known in the art. As for step 115, the patterned metal oxide layer 210′ is again etched 140 to remove the exposed portions to retain only the metal oxide layer 210″ beneath the second masked region. Gold metal 225 is then deposited 145 using conventional e-beam methods thereby forming the first and second electrical contacts. The second patterned photoresist 220′ is then removed in a lift-off process which removes the gold 225 deposited thereon leaving the first and second electrical contacts 225′.

Such steps correlate with steps (viii) to (xi) described herein in respect of the first method of manufacturing the precursor.

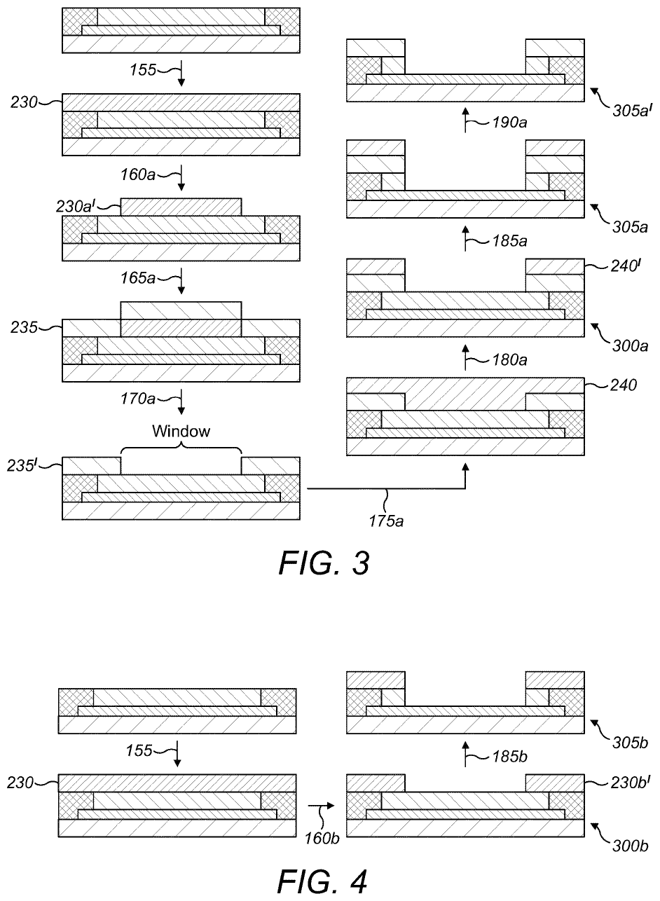

FIG. 3 illustrates a method of forming a passivation layer to define an uncoated window of exposed metal oxide by photolithography, and etching the window to form a sensor.

A third photoresist 230 is applied 155 to the surface of the patterned metal oxide 210″ and the electrical contacts 225′ and patterned 160a to provide a third masked region defined by the patterned third photoresist 230a′ which is spaced apart from the first and second electrical contacts 225′, typically by at least 0.5 μm. A passivation layer 235 is then formed 165a across the stack. For example, an aluminium oxide layer 235 is formed by ALD 165a. The third patterned photoresist 230a′ is then removed 170a to expose a window of the patterned metal oxide layer 210″ leaving the patterned passivation layer 235′ on the first and second electrical contacts 225′ and adjacent portions of the metal oxide layer 210″.

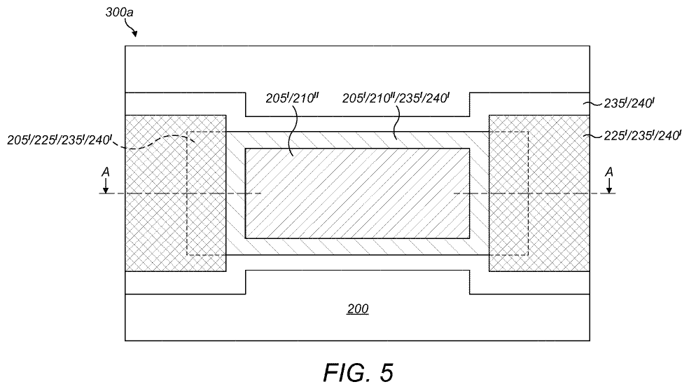

A fourth photoresist 240 is then applied 175a to the stack and patterned 180a to provide a patterned fourth photoresist 240′ as a mask on the patterned passivation layer 235′ to protect said layer and leaving the window exposed. The product is a suitable precursor 300a for the method for the manufacture of a graphene sensor. FIG. 5 is a plan view of a precursor 300a with the layers of the precursor shown with transparency to show the underlying layers for clarity. The cross-section A-A provides the cross section of precursor 300a as shown in FIG. 3.

Such steps correlate with steps (xii-a) to (xiv-a) described herein in respect of manufacturing the precursor.

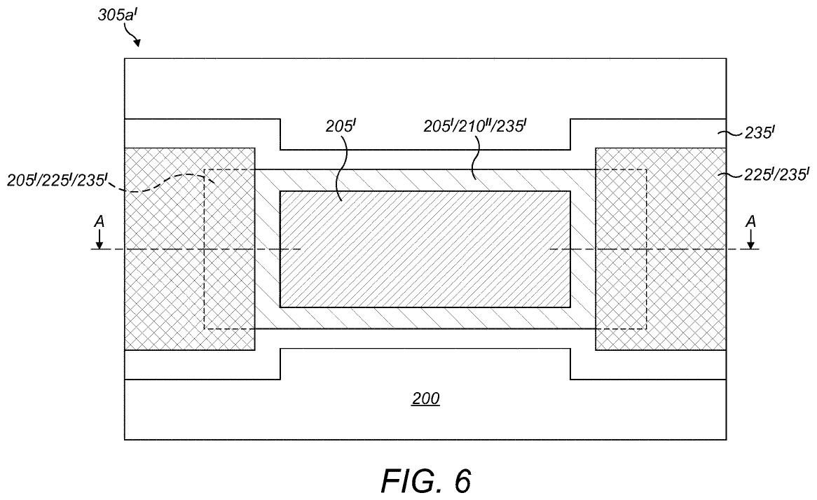

The uncoated window of the patterned metal oxide layer 210″ is then etched 185a using a dilute aqueous alkaline solution, such as a diluted solution of MF351 developer, to expose a surface of the underlying graphene 205′ thereby forming a graphene sensor 305a having an exposed sample surface. The patterned fourth photoresist 240′ of the graphene sensor 305a may be removed providing a graphene sensor 305a′. FIG. 6 is a plan view of a graphene sensor 305a′ with the layers of the precursor shown with transparency to show the underlying layers for clarity. The cross-section A-A provides the cross section of sensor 305a′ as shown in FIG. 3.

FIG. 4 illustrates another method of forming a passivation layer to define an uncoated window of exposed metal oxide by photolithography, and etching the window to form a sensor.

A third photoresist 230 is applied 155 to the surface of the patterned metal oxide 210″ and the electrical contacts 225′ much like the first step in FIG. 3. The third photoresist 230 is then patterned 160b to provide a third masked region defined by the patterned third photoresist 230b′ (which therefore acts as a passivation layer) which is on and across the first and second electrical contacts 225′ and adjacent portions of the patterned metal oxide layer 210″. As will be appreciated, the third masked region is equivalent to the pattern of the passivation layer produced in the method illustrated in FIG. 3.

Such a step correlates with step (xii-b) described herein in respect of manufacturing the precursor.

The uncoated window of the patterned metal oxide layer 210″ is then etched 185b using a dilute aqueous alkaline solution to expose a surface of the underlying graphene 205′ thereby forming a graphene sensor 305b having an exposed sample surface.

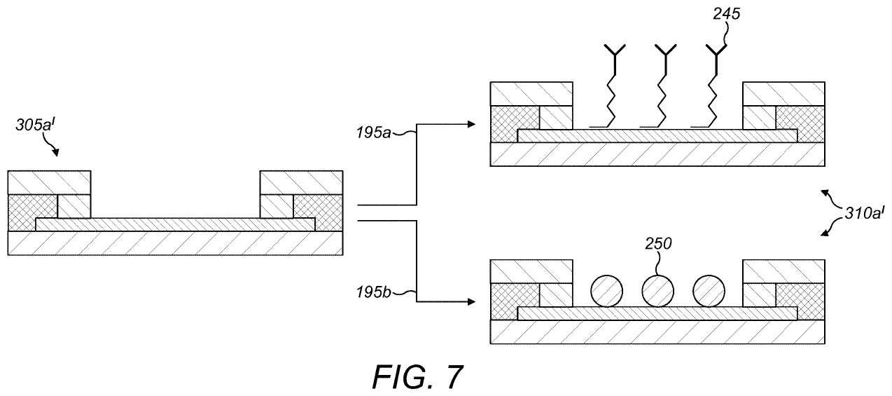

FIG. 7 illustrates two methods of functionalising the exposed sample surface of a graphene sensor 305a to provide a graphene sensor 310a′. In one method, graphene sensor 305a′ having an exposed unfunctionalised sample surface, as obtained by the methods shown in FIGS. 1 to 3, is functionalised 195a by immobilisation of a bioreceptor 245 onto the graphene surface. The bioreceptor 245 comprises a pyrene unit which serves as the anchor to the graphene surface by π-π stacking interactions and at the other end comprises an antibody suitable for binding an analyte of interest. In a second method, the graphene sensor 305a′ is functionalised with metal nanoparticles 250.

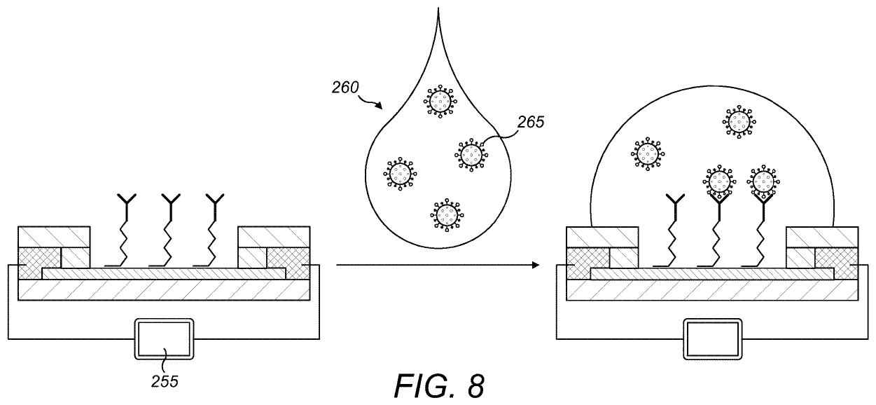

FIG. 8 illustrates a method of testing for an analyte in a sample composition using a graphene biosensor. A graphene biosensor 310a′ is wired via the first and second electrical contacts to a circuit. The circuit comprises an integrated electronics and display 255 for processing the resulting signals and displaying the result of the test. A sample composition 260 for testing may or may not comprise the analyte of interest, such as a virus 265. The sample composition 260 (about 100 μL) is applied to the functionalised sample surface of the graphene biosensor 310a′ and does not contact the first or second electrical contacts 225′ due to the protective patterned passivation layer 235′. The virus 265 binds with the antibody of the bioreceptor 245 causing a change in the electronic properties of the proximal graphene layer structure which in turn results in a modulation of the electronic signal which can be detected, processing and analysed to yield a result, e.g. a change in the Dirac point of the graphene 205′ whereby a predetermined change may be used to ascertain a positive or negative result for the test.

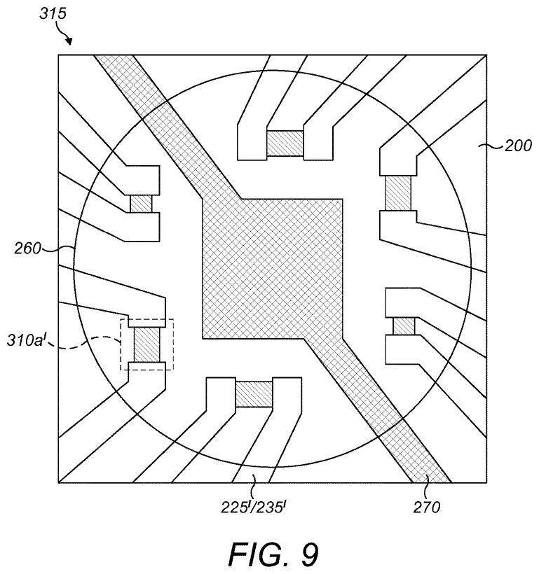

FIG. 9 is a plan view of a graphene biosensor device in use, comprising a plurality of graphene biosensors on a common substrate which comprises a third electrical gate contact. The graphene biosensor device 315 comprises a plurality of graphene biosensors 310a′ on a common substrate 200. Each graphene biosensor 310a′ may have the same or different functionalised surface. The device 315 further comprises a third electrical contact 270 which acts as a gate which may be formed and patterned during the same step(s) for the formation of the first and second electrical contacts. In use, the sample composition 260 is applied to all of the graphene biosensors 310a′, simultaneously contacting the gate contact 270.

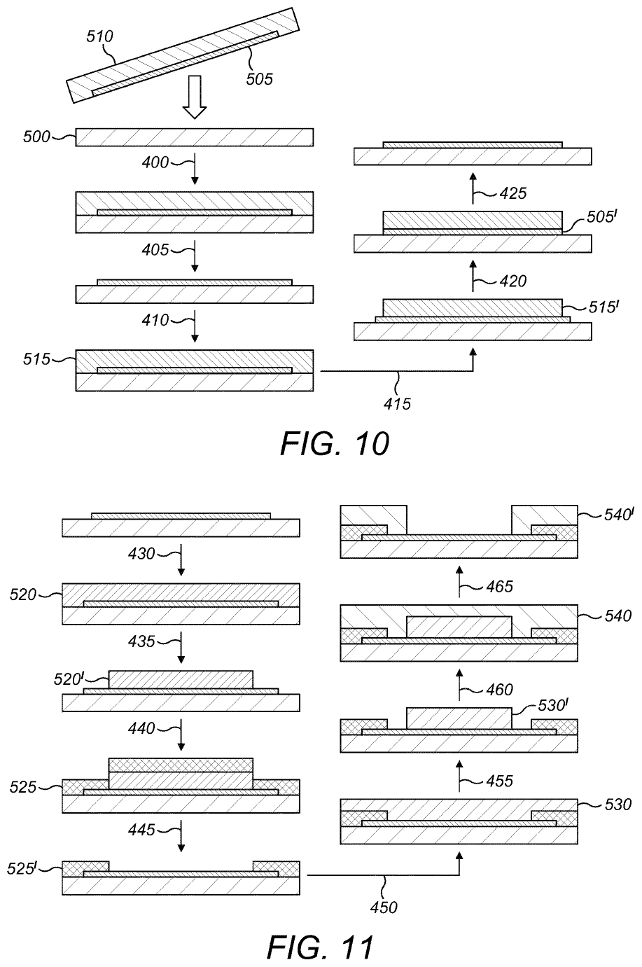

FIG. 10 illustrates a method of transferring graphene to a substrate and patterning by photolithography. FIG. 11 illustrates a method of forming electrical contacts and a passivation layer over said contacts by photolithography. The inventors devised the method(s) shown in FIGS. 10 and 11 in order to provide a passivation layer on the first and second electrical contacts. However, using such conventional photolithography techniques common in the art, the method inevitably gave rise to photoresist and residues on the surface of the graphene. It is understood that this sequence of steps would be consistent with a method suitable for the production of known biosensor devices, such as those acknowledged in the background art section.

A graphene monolayer 505 is grown by CVD on a sacrificial copper foil substrate (not shown). A graphene transfer polymer 510 is spin coated across the graphene 505 and the copper foil etched away, such as by a ferric chloride solution (not shown). The graphene 505 supported by the graphene transfer polymer is transferred 400 to the surface of a substrate 500, for example sapphire. The graphene 505 is already contaminated with polymer and the graphene may also be contaminated with copper residues (whereas the present invention is also devoid of copper residues). The graphene transfer polymer is removed 405 by washing with a solvent before a first photoresist 515 is applied 410 to the graphene 505 and patterned 415 to provide a patterned photoresist 515′. Such steps may not be necessary, though are typically required so as to pattern the graphene 505 into a desired shape. The exposed portions of the graphene 505 are then plasma etched 420 to provide a patterned graphene 505′ at which point the first patterned photoresist 515′ is then removed 415.

A second photoresist 520 is then applied 430 to the surface of the patterned graphene 505′ and itself patterned 435 to provide a patterned second photoresist 520′ which exposes portions of the graphene 505′. Metal 525 is then deposited and the photoresist 520′ removed to leave first and second electrical contacts 525′. A third photoresist 530 is again applied 450 to the surface of the graphene 505′ and patterned 455 to provide a third patterned photoresist 530′ which is separated from the first and second electrical contacts 525′. A passivation layer 540 of aluminium oxide is then deposited 460, such as by ALD, and the photoresist remove 465 to leave patterned passivation layer 540 covering the first and second electrical contacts 525′. The exposed graphene sample surface is nevertheless contaminated with residues which cannot be completely removed to the extent that the graphene is devoid of residues.

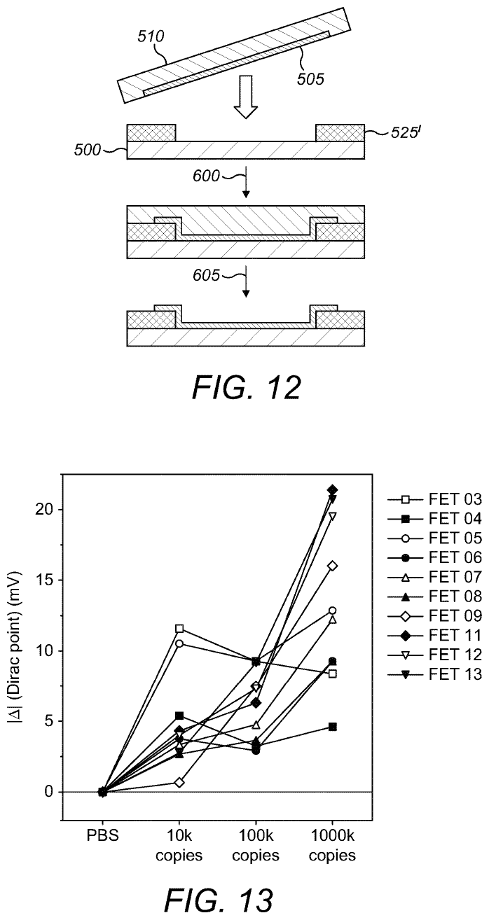

FIG. 12 illustrates a method of transferring graphene to a pre-patterned substrate comprising electrical contacts. In methods known in the art, graphene 505 supported by a graphene transfer polymer 510 (obtained by CVD growth of graphene on catalytic metal substrates) is transferred 600 onto a pre-patterned substrate 500 comprising pre-patterned first and second electrical contacts 525′. The polymer 510 can be removed leaving behind the inevitable residues. Such a method avoids the need for photolithography to deposit the contacts though further photolithography steps would be required to deposit the passivation layer. The method of the present invention is not suitable for forming graphene in a substrate comprising metal electrical contacts on the surface thereof due to the requirement that graphene is formed directly on a non-metallic surface of a substrate by CVD.

FIG. 13 is a plot of the shift in Dirac point observed (in mV) of ten comparative COVID aptamer functionalised GFET (graphene field effect transistor) biosensors manufactured using conventional photolithography upon sequential addition of 10 k, 100 k and 1,000 k copies of deactivated COVID virus.

The geometry of the COVID-19 FET sensor was designed using a graphene channel conjugated to the SARS-COV-2 spike antibody, and the FET was covered with phosphate-buffered saline (PBS; pH 7.4) buffer as the electrolyte to maintain an efficient gating effect.

The results show that a graphene biosensor manufactured using conventional photolithography leaving behind residues, each sensor provides a relatively inconsistent response to increasing numbers of the virus to be detected. Some of the sensors unexpectedly produce a greatest response with only 10 k copies of the virus and this reduces the reliability of the sensor to give a true result. The change in Dirac point of the sensors ranges from about 1 to about 10 mV at 10 k copies (generally about 4 or 5 mV) to about 5 to about 20 mV at 1,000 k copies, which is illustrative of the sensitivity.

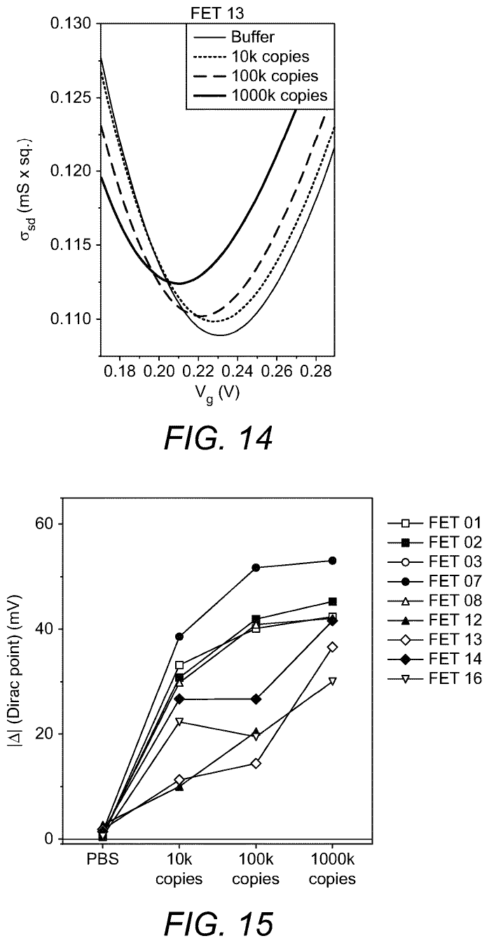

FIG. 14 is an exemplary I-V trace of a comparative biosensor, specifically FET 13 of FIG. 13. FET 13 exhibits the second highest change in Dirac point at 1,000 k copies as illustrated in FIG. 13. The Dirac point, as measured as the minimum of the trace, remains substantially unchanged at about 0.23 V from the PBS buffer to 10 k copies. At 100 k copies, the Dirac point can be seen at about 0.22 V and at 1,000 k (1M copies), the Dirac point is about 0.21 V.

FIG. 15 is a plot of the shift in Dirac point observed (in mV) of nine COVID aptamer functionalised GFET biosensors in accordance with the present invention upon sequential addition of 10 k, 100 k and 1,000 k copies of deactivated COVID virus.

The results shows that the graphene biosensor manufactured by etching a window in a metal oxide layer which served to protect the graphene from any contact with photoresist and other polymers provide a more consistent output which reliably increases with an increase in the number of copies of deactivated virus. Moreover, the change in Dirac point of the sensors ranges from about 10 to about 35 mV at 10 k copies (generally about 20 to 30 mV) to about 30 to about 50 at 1,000 k copies, which is illustrative of the significantly increased sensitivity of the sensor of the invention over a comparative sensor.

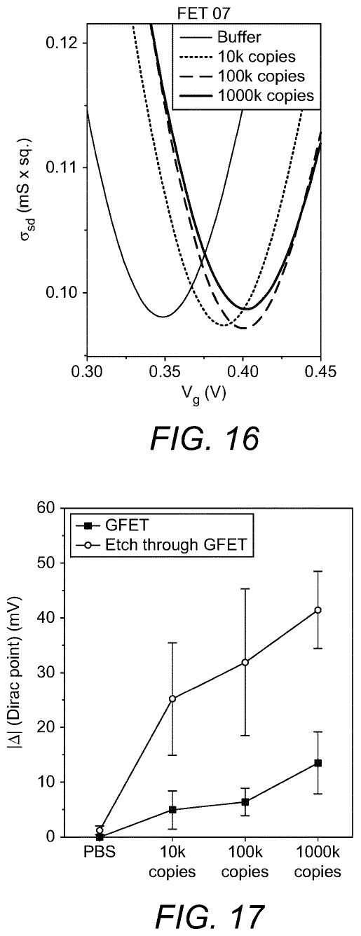

FIG. 16 is an exemplary I-V trace of a biosensor in accordance with the present invention, specifically FET 07 of FIG. 15. FET 07 exhibits the highest change in Dirac point at 1,000 k copies as illustrated in FIG. 15. The Dirac point, as measured as the minimum of the trace, shifts substantially from about 0.35 V with the PBS buffer to about 0.39 V at 10 k copies. At 100 k and 1,000 k copies, the Dirac point can be seen at about 0.40 V.

As illustrated by the comparison of FIGS. 14 and 16, the inventive biosensors have a higher transconductance (a steeper gradient) which relates to a higher mobility of the graphene which is also believed to result in improved sensitivity. Moreover, the measured conductivity at the Dirac point (and correspondingly across respective gate voltages) remains consistent across the different amounts of virus added. That is, the Dirac point as shown in FIG. 16 retains a conductivity (σ_{sd}) of about 0.975 mS×sq. whereas as significant change in conductivity at the Dirac point is observed in the comparative with conductivity varying from just below 0.110 mS×sq. to 0.113 mS×sq. These improvements allow for quality checking and improves the reliability of the device in that calibration is much improved and a more consistent signal from each channel can be obtained.

FIG. 17 is a plot of the average changes and calculated standard deviations for the data shown in FIGS. 13 and 15. FIG. 17 is a direct comparison of the average Dirac points shifts for GFET (FIG. 13) and etch through GFET (FIG. 15) COVID biosensors.

The performance of a metal oxide layer as a protective layer on top of graphene in the manufacture of a biosensor was investigated by comparison without use of such a layer. Monolayer graphene was first grown on sapphire substrates in an MOCVD reactor. In some samples, this was followed by growth of an additional 20 nm of aluminium oxide (AlOx) by ALD. Biosensors/liquid gated graphene field effect transistors (FETs) were fabricated from both the bare graphene and the aluminium oxide coated graphene using photolithography as described herein. The final step in the device fabrication is the exposure of the graphene surface which is achieved by washing the photoresist from the bare graphene or wet etching the sacrificial aluminium oxide layer.

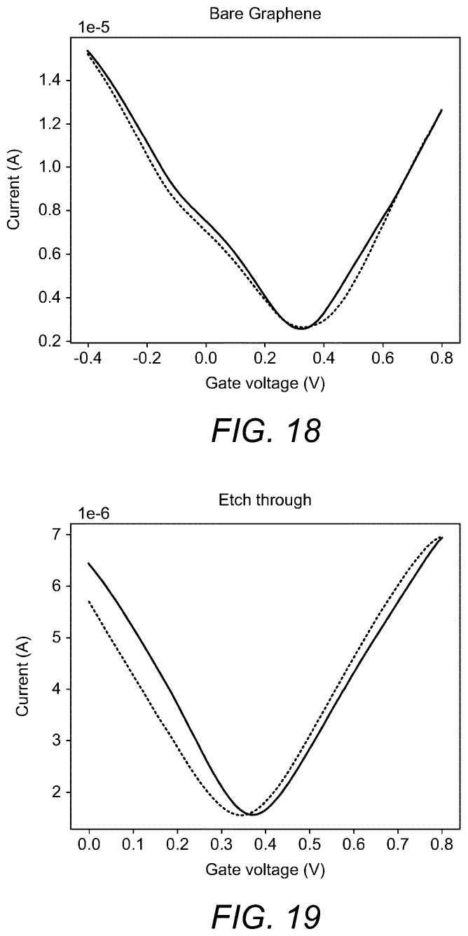

Following device fabrication, the FETs were soaked for 1 hour at room temperature in a conventional Phosphate Buffered Saline solution which is used in subsequent biofunctionalization steps. After soaking, the samples were rinsed with DI water and a 10 mM KCI solution was pipetted onto the FETs, and an Ag/AgCl gate electrode was immersed in the solution. For each device the I-V characteristic was measured by applying a 40 mV source-drain bias, whilst sweeping the gate voltage from 0 to 0.6 V. The gate voltage was swept in both forward and backward directions with a sweep rate of 22.5 mV/s. The results are shown in FIGS. 18 and 19.

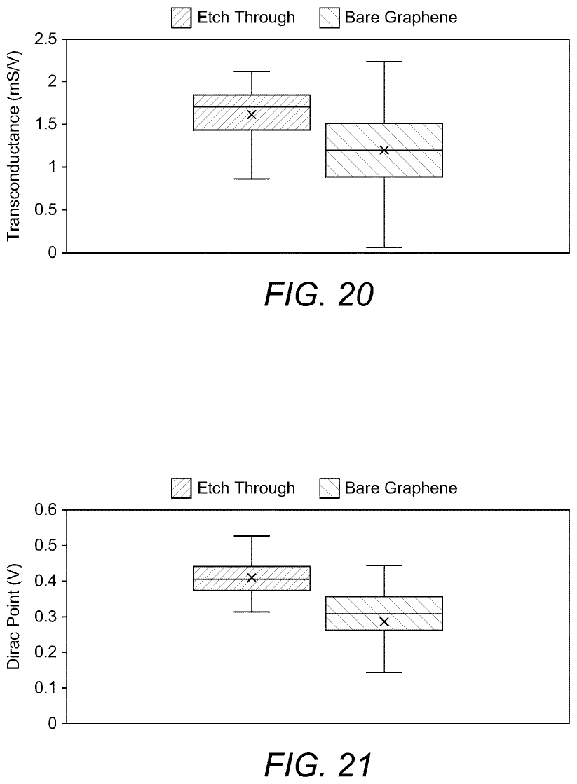

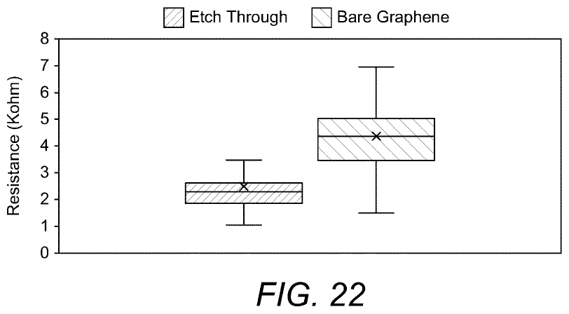

From the I-V characteristics, the transconductance and Dirac point were extracted and the channel resistance measured independently using a two terminal measurement and a multimeter. The results are shown in FIGS. 20 to 22 which are box plots comparing the electrical performance of aluminium oxide protected FETs, i.e. “etch through” (which is shown on the left hand side of each Figure), with that of FETs manufactured from “bare graphene” (which is shown on the right hand side of each Figure).

The devices manufactured using the “etch through” process consistently exhibit lower resistances (e.g. less than 4.5 kΩ) and lower variance in device resistances. The reasoning for the improved FET performance is a result of the cleaner processing method of manufacture. Moreover, in relation to applications in sensing, an increased transconductance should allow for higher device sensitivity as a sensing event will generate a larger change in current. Therefore, it is particularly advantageous that the devices demonstrate about a 35% increase in transconductance. The “etch through” devices also demonstrate a lower variance in the Dirac point measured after device fabrication. Higher consistency of devices is desirable for ensuring consistent sensing.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1.-2. (canceled)

3. A graphene sensor comprising:
a graphene layer structure provided on a non-metallic surface of a substrate, the graphene layer structure having an exposed sample surface for receiving a sample for testing;
first and second electrical contacts provided in contact with the graphene layer structure, and arranged on opposite sides of the sample surface;
wherein each electrical contact is separated from the sample surface by an adjacent metal oxide layer, and wherein each electrical contact and adjacent metal oxide layer are capped with a passivating layer; and
wherein the sample surface is devoid of photoresist.

4. The graphene sensor according to claim 3, wherein the metal oxide layer is aluminium oxide.

5. The graphene sensor according to claim 3, wherein the graphene layer structure is a graphene monolayer.

6. The graphene sensor according to claim 3, wherein the passivating layer comprises aluminium oxide, silicon oxide, silicon nitride, photoresist and/or synthetic resin.

7. The graphene sensor according to claim 3, wherein the thickness of the metal oxide layer is from 2 nm to 5 μm.

8. The graphene sensor according to claim 3, wherein the width of the metal oxide layer is at least 0.5 μm.

9. The graphene sensor according to claim 3, wherein the thickness of the passivation layer is at least 5 nm.

10. A container for storage and shipping, containing a plurality of precursors for the manufacture of a graphene sensor, wherein each precursor comprises:
a graphene layer structure provided on a non-metallic surface of a substrate, wherein the graphene layer structure is formed on the non-metallic surface of the substrate by CVD;
first and second electrical contacts in contact with the graphene layer structure, and arranged on opposite sides of the precursor;
a metal oxide layer on and across the graphene layer structure, in contact with and between the first and second electrical contacts; and
a passivating layer provided on the metal oxide layer and on and across the first and second electrical contacts, defining an uncoated window of exposed metal oxide layer, the window arranged between the first and second electrical contacts.

11. A method for the manufacture of a graphene sensor, the method comprising:
(i) providing a precursor comprising:
a graphene layer structure on a non-metallic surface of a substrate, wherein the graphene layer structure is formed on the non-metallic surface of the substrate by CVD;
first and second electrical contacts in contact with the graphene layer structure, and arranged on opposite sides of the precursor;
a metal oxide layer on and across the graphene layer structure, in contact with and between the first and second electrical contacts; and
a passivating layer provided on the metal oxide layer and on and across the first and second electrical contacts, defining an uncoated window of exposed metal oxide layer, the window arranged between the first and second electrical contacts;
(ii) etching the uncoated window of exposed metal oxide layer to form a graphene sensor having an exposed sample surface of the graphene layer structure for receiving a sample for testing; and optionally
(iii) functionalising the exposed sample surface to form a graphene sensor having a functionalised sample surface for receiving a sample for testing.

12. The method according to claim 11, wherein the graphene sensor is in accordance with claim 1.

13. The method according to claim 11, wherein the precursor is obtained in a method comprising:
(i) providing a substrate having a non-metallic surface;
(ii) forming a graphene layer structure on the non-metallic surface by CVD;
(iii) forming a metal oxide layer on and across the graphene layer structure;
(iv) applying a first photoresist to the metal oxide layer and patterning it to provide a first masked region;
(v) etching the metal oxide layer to retain only the metal oxide layer beneath the first masked region, exposing a portion of the graphene layer structure;
(vi) plasma etching the exposed portion of the graphene layer structure to retain only the graphene layer structure beneath the first masked region;
(vii) removing the first photoresist;
(viii) applying a second photoresist to the metal oxide layer and patterning it to provide a second masked region;
(ix) etching the metal oxide layer to retain only the metal oxide layer beneath the second masked region, exposing a portion of the graphene layer structure;
(x) depositing metal to form first and second electrical contacts, each in contact with the exposed graphene layer structure and an edge of the metal oxide layer; and
(xi) removing the second photoresist.

14. The method according to claim 11, wherein the precursor is obtained in a method comprising:
(i) providing a substrate having a non-metallic surface;
(ii) forming a graphene layer structure on the non-metallic surface by CVD;
(iii) forming a patterned metal oxide layer on the graphene layer structure;
(vi) plasma etching the graphene layer structure to retain only the graphene layer structure beneath the patterned metal oxide layer;
(viii) applying a second photoresist to the metal oxide layer and patterning it to provide a second masked region;
(ix) etching the metal oxide layer to retain only the metal oxide layer beneath the second masked region, exposing a portion of the graphene layer structure;
(x) depositing metal to form first and second electrical contacts, each in contact with the exposed graphene layer structure and an edge of the metal oxide layer; and
(xi) removing the second photoresist.

15. The method according to claim 11, wherein the precursor is obtained in a method comprising:
(I) providing a substrate having a non-metallic surface;
(II) forming a graphene layer structure on the non-metallic surface by CVD;
(III) forming a metal oxide layer on and across the graphene layer structure;
(IV) applying a first photoresist to the metal oxide layer and patterning it to provide a first masked region;
(V) etching the metal oxide layer to retain only the metal oxide layer beneath the first masked region, exposing a portion of the graphene layer structure;
(VI) depositing metal to form first and second electrical contacts, each in contact with the exposed graphene layer structure and an edge of the metal oxide layer;
(VII) removing the first photoresist;
(VIII) applying a second photoresist to the metal oxide layer and the first and second electrical contacts, and patterning it to provide a second masked region covering the first and second electrical contacts and a portion of the metal oxide layer;
(IX) etching the metal oxide layer to retain only the metal oxide layer beneath the second masked region, exposing a portion of the graphene layer structure;
(X) plasma etching the exposed portion of the graphene layer structure to retain only the graphene layer structure beneath the second masked region; and
(XI) removing the second photoresist.

16. The method according to claim 13, wherein the precursor is obtained in a method which further comprises:
(xii-a) applying a third photoresist and patterning it to provide a third masked region on a portion of the metal oxide layer spaced apart from the first and second electrical contacts;
(xiii-a) forming a passivation layer on the first and second electrical contacts and adjacent unmasked metal oxide layer;
(xiv-a) removing the third photoresist.

17. The method according to claim 16, wherein the precursor is obtained in a method which further comprises:
(xv-a) applying a fourth photoresist and patterning it to provide a mask on and across the passivation layer.

18. The method according to claim 13, wherein the precursor is obtained in a method which further comprises:
(xii-b) applying a third photoresist and patterning it to provide a third masked region on the first and second electrical contacts and adjacent portions of the metal oxide layer.

19.-20. (canceled)

21. The graphene sensor according to claim 3, wherein the exposed sample surface of the graphene layer structure is functionalised.

22. The graphene sensor according to claim 21, wherein the graphene sensor is a biosensor.

23. The graphene sensor according to claim 3, wherein the thickness of the metal oxide layer is from 5 nm to 1 μm.
